(19) United States
(12) Patent Application Publication
(10) Pub. No.: US 2026/0291174 A1
(43) Pub. Date: Sep. 24, 2026

(54) OPTICAL SEMICONDUCTOR DEVICE, OPTICAL TRANSMISSION DEVICE EQUIPPED WITH OPTICAL SEMICONDUCTOR DEVICE, AND METHOD FOR MANUFACTURING OPTICAL TRANSMISSION DEVICE

(71) Applicant: Mitsubishi Electric Corporation, Tokyo (JP)

(72) Inventor: Shinya OKUDA, Tokyo (JP)

(73) Assignee: Mitsubishi Electric Corporation, Tokyo (JP)

(21) Appl. No.: 18/873,579

(22) PCT Filed: Sep. 8, 2022
(86) PCT No.: PCT/JP2022/033630

§ 371 Date: Dec. 10, 2024

(51) Int. Cl. H01S 5/042; H01S 5/026; H01S 5/062

(52) U.S. Cl. CPC H01S 5/04256; H01S 5/026; H01S 5/04252; H01S 5/062

(57) ABSTRACT

A method for manufacturing an optical transmission device of the present disclosure includes the steps of: disposing an optical semiconductor device on a sub-mount, the optical semiconductor device including a semiconductor laser formed above a semiconductor substrate, an optical modulation element formed above the semiconductor substrate, an electrostatic discharge withstand element formed above the semiconductor substrate, and a temporary electrode electrically connecting the optical modulation element and the electrostatic discharge withstand element in parallel; connecting electrically the optical semiconductor device and a drive circuit; and cutting electrically the temporary electrode of the optical semiconductor device disposed on the sub-mount.

### TECHNICAL FIELD

The present disclosure relates to an optical semiconductor device, an optical transmission device equipped with an optical semiconductor device, and a method for manufacturing an optical transmission device.

### BACKGROUND ART

An electro-absorption modulated laser (EML) is an optical semiconductor device that integrates a semiconductor laser and an optical modulation element, which absorbs part of the incident light when an electric field is applied, on the same semiconductor substrate. Compared to direct modulation systems, which directly modulate the light intensity, the EML has less signal waveform degradation and enables high-speed, long-distance optical fiber transmission.

As data traffic increases, EML operation is required to be further increased in speed. Modulating the EML at high speed requires reducing the electrostatic capacitance of an optical modulation element. Unfortunately, reducing the electrostatic capacitance of the optical modulation element also reduces the electrostatic breakdown voltage of the optical modulation element. The decrease in the electrostatic breakdown voltage of the optical modulation element also decreases the electrostatic breakdown voltage of the EML, and there is a risk that the EML is destroyed by static electricity applied by machinery or workers during the process of mounting the EML on a substrate or during the process of inspecting the characteristics of the EML. For this reason, various measures are taken to eliminate static electricity when mounting and inspecting the EML. For example, to eliminate static electricity from workers, workers wear work clothes made from anti-static materials, or the humidity of the work environment is controlled and the work environment is kept electrically neutral at all times using ionizers or the like. Unfortunately, such measures have limits, and in the case of semiconductor devices with the electrostatic breakdown voltage of approximately 100 V or less, there is a high possibility of being destroyed during mounting and inspection.

As a technology for preventing semiconductor devices from being destroyed by static electricity, Patent Document 1 (Japanese Laid-Open Patent Publication No. 2004-6548) discloses a technology for improving the electrostatic breakdown voltage of the semiconductor laser by forming a voltage-withstand element.

### CITATION LIST

### Patent Document

Patent Document 1: Japanese Laid-Open Patent Publication No. 2004-6548

### SUMMARY OF THE INVENTION

### Problem to be Solved by the Invention

Unfortunately, when the technology described in Patent Document 1, which targets semiconductor lasers, is applied to the optical modulation element of the EML, the electrostatic breakdown voltage is improved, whereas, the electrostatic capacitance of the optical modulation element increases, which is a problem that cannot be applied to high-speed modulation applications.

The present disclosure has been made to solve the above problem, and an object of the present disclosure is to provide a method for manufacturing an optical transmission device that enables high-speed modulation while improving the electrostatic breakdown voltage during mounting, and an optical semiconductor device suitable for the optical transmission device.

### Means to Solve the Problem

A method for manufacturing an optical transmission device according to the present disclosure comprising the steps of: disposing an optical semiconductor device on a sub-mount, the optical semiconductor device including a semiconductor laser formed above a semiconductor substrate, an optical modulation element formed above the semiconductor substrate, an electrostatic discharge withstand element formed above the semiconductor substrate, and a temporary electrode electrically connecting the optical modulation element and the electrostatic discharge withstand element in parallel; connecting electrically the optical semiconductor device and a drive circuit; and cutting electrically the temporary electrode of the optical semiconductor device disposed on the sub-mount.

### Effect of the Invention

According to the present disclosure, it is capable of providing an optical transmission device that enables high-speed modulation while improving the electrostatic breakdown voltage during mounting, and an optical semiconductor device suitable for the optical transmission device.

### BRIEF DESCRIPTION OF THE DRAWINGS

FIG. 1 is a top view of an optical semiconductor device 1 according to Embodiment 1;

FIG. 2 is a cross-sectional schematic view of the optical semiconductor device 1 along the A-A line, according to Embodiment 1;

FIG. 3 is a cross-sectional schematic view of the optical semiconductor device 1 along the B-B line, according to Embodiment 1;

FIG. 4 is a cross-sectional schematic view of the optical semiconductor device 1 along the C-C line, according to Embodiment 1;

FIG. 5 is a top view of the optical semiconductor device 1 with a temporary electrode 10 cut off, according to Embodiment 1;

FIG. 6 is a cross-sectional schematic view of the optical semiconductor device 1 along the D-D line with the temporary electrode 10 cut off, according to Embodiment 1;

FIG. 7 is an equivalent circuit diagram of the optical semiconductor device 1 before static electricity is applied, according to Embodiment 1;

FIG. 8 is an equivalent circuit diagram of the optical semiconductor device 1 after static electricity is applied, according to Embodiment 1;

FIG. 9 shows the time variation of voltage applied to an optical modulation element 4 when 100 V of static electricity is applied;

FIG. 10 shows a perspective view of an optical transmission device in the step of disposing the optical semiconductor device on the sub-mount;

FIG. 11 is a perspective view of the optical transmission device in the step of electrically connecting the optical semiconductor device and a drive circuit;

FIG. 12 is a perspective view of the optical transmission device in the step of electrically cutting the temporary electrode of the optical semiconductor device disposed on the sub-mount;

FIG. 13 is a cross-sectional schematic view of an optical semiconductor device according to Embodiment 4;

FIG. 14 is a top view of an optical semiconductor device according to Embodiment 5;

FIG. 15 is a top view of an optical semiconductor device according to Embodiment 6.

### DESCRIPTION OF EMBODIMENTS

The following is an example of a semiconductor optical integrated circuit related to the present disclosure, but it is not limited to the embodiments shown below, and it can be arbitrarily transformed and implemented within the scope of not deviating from the gist of the present disclosure. Note that, for convenience, some parts that are repeated explanations may be omitted.

### Embodiment 1

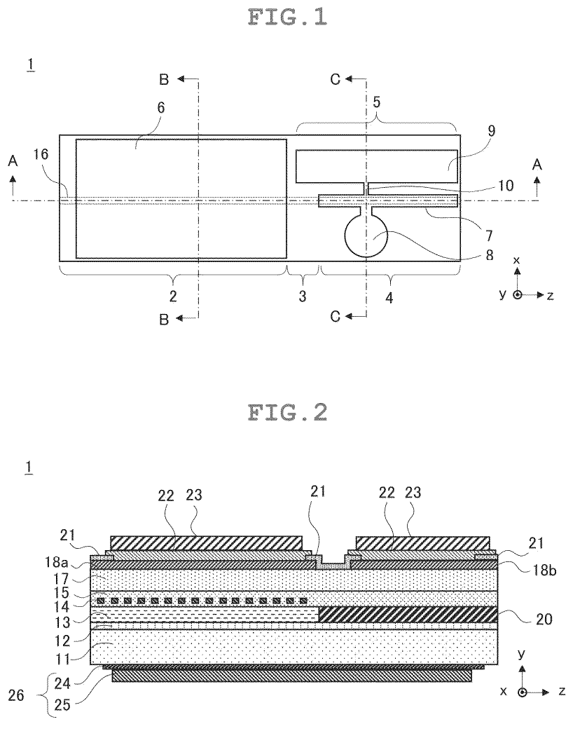

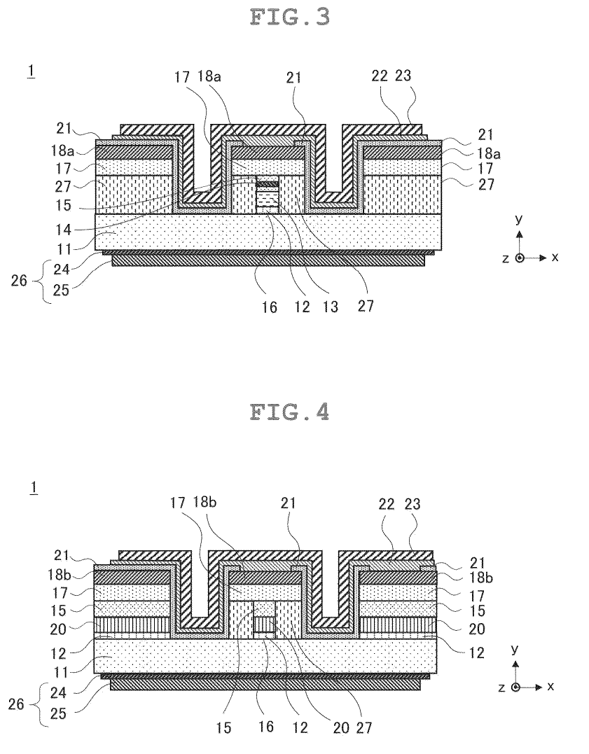

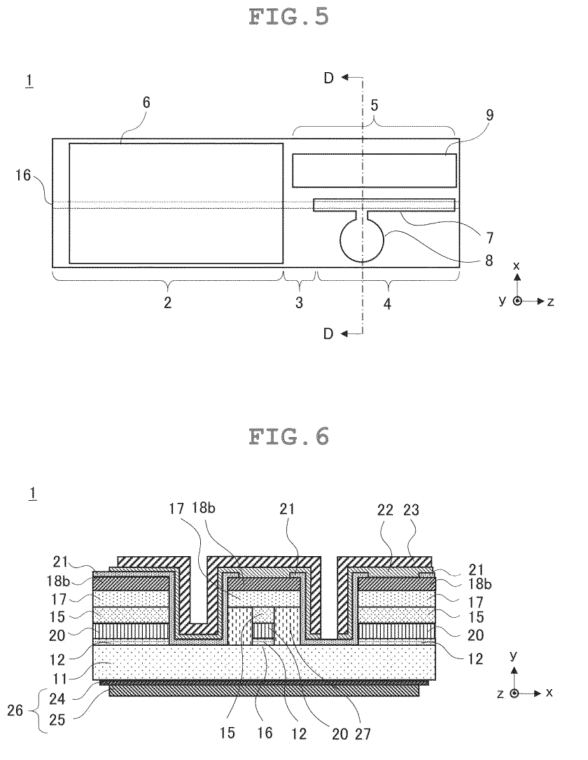

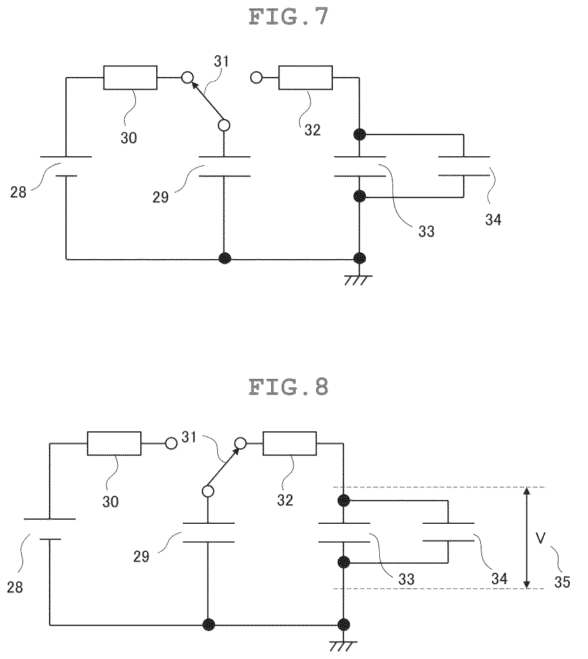

FIG. 1 is a top view of an optical semiconductor device 1 according to Embodiment 1. FIG. 2 is a cross-sectional schematic view of the optical semiconductor device 1 along the A-A line, according to Embodiment 1. FIG. 3 is a cross-sectional schematic view of the optical semiconductor device 1 along the B-B line, according to Embodiment 1, showing a cross-sectional view of a semiconductor laser 2. FIG. 4 is a cross-sectional schematic view of the optical semiconductor device 1 along the C-C line, according to Embodiment 1, showing a cross-sectional view of an optical modulation element 4 and an electrostatic discharge withstand element 5. FIG. 5 is a top view of the optical semiconductor device 1 with a temporary electrode 10 cut off, according to Embodiment 1. FIG. 6 is a cross-sectional schematic view of the optical semiconductor device 1 along the D-D line with the temporary electrode 10 cut off, according to Embodiment 1. FIG. 7 is an equivalent circuit diagram of the optical semiconductor device 1 according to Embodiment 1 before static electricity is applied. FIG. 8 is an equivalent circuit diagram of the optical semiconductor device 1 according to Embodiment 1 after static electricity is applied.

The optical semiconductor device 1 according to Embodiment 1 includes: the semiconductor laser 2; an isolation section 3; the optical modulation element 4; and the electrostatic discharge withstand element 5, as shown in FIGS. 1 and 2. An anode electrode 6 is formed on the surface of the semiconductor laser 2, an anode electrode 7 is formed on the surface of the optical modulation element 4, and an anode electrode 9 is formed on the surface of the electrostatic discharge withstand element 5. The anode electrode 7 on the optical modulation element 4 is connected to a bonding pad electrode 8. In addition, the anode electrode 7 on the optical modulation element 4 is connected to the anode electrode 9 on the electrostatic discharge withstand element 5 through the temporary electrode 10. The semiconductor laser 2 is formed as a distributed feedback laser. The optical modulation element 4 is formed with an electro-absorption type semiconductor modulator. By inputting an electrical signal to the anode electrode 7 through the bonding pad electrode 8, the optical modulation element 4 absorbs and modulates the laser light emitted from the semiconductor laser 2. As for the wavelength band of light, any wavelength band used in optical communication is acceptable. For example, there are generally short wavelength bands and long wavelength bands used in optical fiber communication, and the 1.3 μm wavelength band and the 1.55 μm wavelength band are used as examples of long wavelength bands. The isolation section 3 electrically isolates the semiconductor laser 2 and the optical modulation element 4 by separating the p-type contact layer 18a connected to the anode electrode 6 of the semiconductor laser 2 and the p-type contact layer 18b connected to the anode electrode 7 of the optical modulation element 4. A mesa stripe 16 is formed continuously in the semiconductor laser 2, the isolation section 3, and the optical modulation element 4. The mesa stripe 16 is a waveguide that propagates the laser beam emitted from the semiconductor laser 2. In each figures, the z-direction is the direction of the optical axis (propagation direction) of the laser beam emitted from the semiconductor laser 2, and the x-direction is perpendicular to the z-direction and the y-direction, and the x-direction is also the direction in which each semiconductor layer of the optical semiconductor device 1 is extended, and the y-direction is perpendicular to the z-direction and the x-direction, and the y-direction is also the direction in which each semiconductor layer of the optical semiconductor device 1 is stacked.

As shown in FIG. 3, the semiconductor laser 2 is formed with a stacked structure of semiconductors. The semiconductor laser 2 includes: a semiconductor substrate 11 that is an n-type InP substrate; an n-type guide layer 12; an i-type active layer 13; a diffraction grating 14; a p-type guide layer 15; a p-type InP cladding layer 17; the p-type InGaAs contact layer 18a; a buried layer 27; an insulating film 21; the anode electrode 6; and a cathode electrode 26 formed on the back surface of the semiconductor substrate 11. As an example, the guide layer 12, the active layer 13, the diffraction grating 14, and the guide layer 15 are made of III-V compound semiconductors such as InAlGaAs and InGaAsP. The active layer 13 is composed of a multiple quantum well (MQW) structure. The buried layer 27 is made of Fe-doped semi-insulating InP. Note that, the applicable semiconductor materials are not limited to the above-mentioned III-V compound semiconductors, and other semiconductor materials can be applicable. The surface of the contact layer 18a is covered with the insulating film 21 except for the area where the anode electrode 6 is formed, and the anode electrode 6 is connected to the contact layer 18a through the area where the insulating film 21 is not formed. The anode electrode 6 is composed of a first electrode layer 22 that contacts the contact layer 18a, which is a semiconductor layer, and a second electrode layer 23 formed on the first electrode layer 22. The first electrode layer 22 also acts as a barrier metal that prevents the metal of the second electrode layer 23 from diffusing into the contact layer 18a, in addition to increasing the adhesion with the contact layer 18a. As an example of the first electrode layer 22 and the second electrode layer 23, an electrode structure of Ti/Pt/Au for the first electrode layer 22, starting from the layer in contact with the contact layer 18a, and Au for the second electrode layer 23 is used. The cathode electrode 26 is composed of a first electrode layer 24 and a second electrode layer 25. The first electrode layer 24 also acts as a barrier metal to prevent the metals of the second electrode layer 25 from diffusing into the semiconductor substrate 11, in addition to increasing the adhesion to the semiconductor substrate 11. As an example of the first electrode layer 24 and the second electrode layer 25, an electrode structure of AuGe/Ni/Ti/Pt/Au for the first electrode layer 24, starting from the layer in contact with the semiconductor substrate 11, and Au for the second electrode layer 25. Note that, the electrode structures of the first electrode layer 22, the second electrode layer 23, the first electrode layer 24, and the second electrode layer 25 are not limited to the combinations described above, and any combination can be applicable.

The optical modulation element 4 is formed with a stacked structure of semiconductors as shown in FIG. 4. The optical modulation element 4 includes: the semiconductor substrate 11; the guide layer 12; an i-type light absorption layer 20; the guide layer 15; the cladding layer 17; the buried layer 27; the p-type InGaAs contact layer 18b; the insulating film 21; the anode electrode 7; and the cathode electrode 26. As an example, the light absorption layer 20 is composed of the MQW structure made of III-V compound semiconductors such as InAlGaAs and InGaAsP. The applicable semiconductor materials are not limited to the above-mentioned III-V compound semiconductors, and other semiconductor materials can be applicable. The surface of the contact layer 18b is covered with the insulating film 21 except for the area where the anode electrode 7 is formed, and the anode electrode 7 is connected to the contact layer 18b through the area where the insulating film 21 is not formed. The anode electrode 7 is composed of the first electrode layer 22 that contacts the contact layer 18b, which is a semiconductor layer, and the second electrode layer 23 formed on the first electrode layer 22. Generally, the optical modulation element 4 is narrow in width to confine light in the mesa stripe 16, and thus the width of the anode electrode 7 formed directly above the mesa stripe 16 is also narrow. For this reason, the bonding pad electrode 8 with a large area is connected to the anode electrode 7, and the modulation signal is input to the optical modulation element 4 through the bonding pad electrode 8.

The electrostatic discharge withstand element 5 is formed with a stacked structure of semiconductors as shown in FIG. 4. The electrostatic discharge withstand element 5 includes: the semiconductor substrate 11; the guide layer 12; the optical absorption layer 20; the guide layer 15; the cladding layer 17; the contact layer 18b; the insulating film 21; the anode electrode 9; and the cathode electrode 26. The surface of the contact layer 18b is covered with the insulating film 21, except for the area where the anode electrode 9 is formed. The anode electrode 9 is connected to the contact layer 18b through the area where the insulating film 21 is not formed. The anode electrode 9 is composed of the first electrode layer 22 that contacts the contact layer 18b, which is a semiconductor layer, and the second electrode layer 23 formed on the first electrode layer 22. The anode electrode 9 is connected to the anode electrode 7 on the optical modulation element 4 through the temporary electrode 10. The electrostatic discharge withstand element 5 has at least some of the same layer structure as the optical modulation element 4, and thus can be formed using the same manufacturing process. Here, “same layer structure” means that the thickness and the composition of the two target layer structures are same, and if the two target layer structures are multilayer structures, it means that the thickness and the composition of each layer of the multilayer structure are same. In addition, the planar shape of the electrostatic discharge withstand element 5 can be any shape as long as it is electrically connected to the optical modulation element 4. FIG. 1 shows an example of a rectangular planar shape for the anode electrode 9 of the electrostatic discharge withstand element 5, but this is not limited to such shape, and for example, it may also be an elliptical shape. Note that, the electrostatic capacitance of the electrostatic discharge withstand element 5 is larger, the effect of improving the electrostatic breakdown withstand voltage is greater, so that the effect of increasing the electrostatic breakdown voltage is greater when the area of the anode electrode 9, which is a planar shape, is larger.

The operation of the optical semiconductor device 1 according to Embodiment 1 will be explained. The driving method of the optical semiconductor device 1 described below is just one example, and various changes are possible within the scope of the present disclosure.

First, in the semiconductor laser 2, the recombination of electrons and holes occurs by applying a voltage between the anode electrode 6 and the cathode electrode 26, and thus light emission due to recombination occurs. The generated light is reflected by the diffraction grating 14 and oscillates back and forth within the semiconductor laser 2. Stimulated emission occurs during the round trip of the light, and the intensity of the light is amplified. When a certain threshold is reached, laser oscillation occurs and laser light is emitted from the semiconductor laser 2 towards the optical modulation element 4. In the optical modulation element 4, when a negative voltage is applied from the anode electrode 7 to the cathode electrode 26 through the bonding pad electrode 8, light absorption occurs due to the quantum confinement Stark effect of the light absorption layer 20. Namely, the intensity of the laser light emitted from the optical modulation element 4 is modulated in response to the voltage value applied to the optical modulation element 4. The modulated laser light is emitted outside the optical semiconductor device 1 and is used as the signal light in optical communication. Note that, the upper limit of the modulation speed is inversely proportional to the electrostatic capacitance of the optical modulation element 4, thus the capacitance of the optical modulation element 4 for high-speed modulation applications is extremely small.

Assume that a voltage caused by static electricity is applied to the optical modulation element 4. The applied voltage caused by static electricity causes a current to flow through the optical modulation element 4. Since the optical modulation element 4 is connected in parallel with the electrostatic discharge withstand element 5, part of the current is distributed to the electrostatic discharge withstand element 5. As a result of the part of the current flowing through the electrostatic discharge withstand element 5, the voltage applied to the optical modulation element 4 decreases, thereby improving the electrostatic breakdown voltage of the optical modulation element 4.

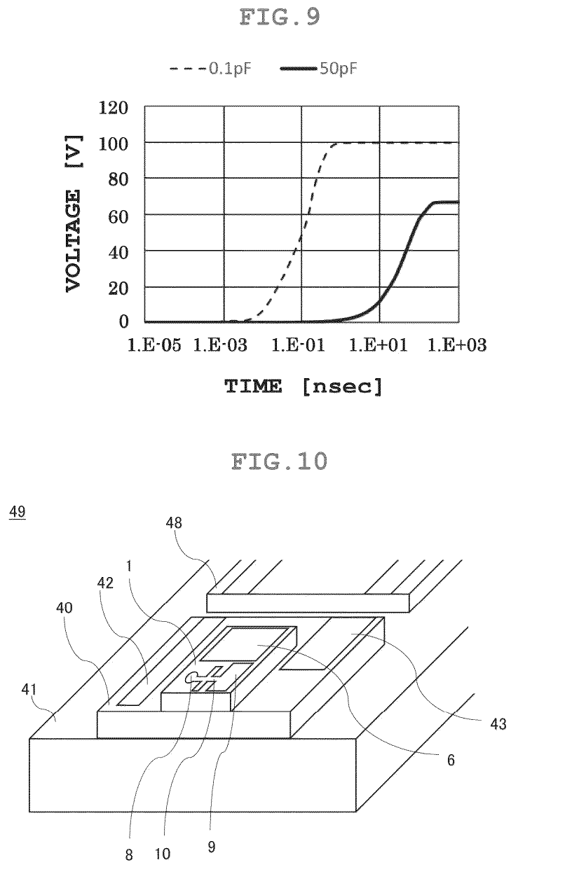

The equivalent circuit diagrams for cases where static electricity is applied from the human body to the optical semiconductor device using the human body model (Human Body Model: HBM) are shown in FIGS. 7 and 8. This equivalent circuit is composed of a voltage source 28, a protective resistance 30, a discharge capacity 29, a discharge resistance 32, a switch 31, an electrostatic capacitance 33 of the optical modulation element 4, and an electrostatic capacitance 34 of the electrostatic discharge withstand element 5. First, before the static electricity is applied to the optical semiconductor device, that is, when the electric charge is charged to the human body as static electricity, as shown in FIG. 7, the electric charge is charged to the discharge capacity 29 through the voltage source 28. The state in which static electricity is applied to the optical semiconductor device is shown in FIG. 8 as the switch 31 switching from the circuit on the protective resistance 30 side to the circuit on the discharge resistance 32 side. When the switch 31 is switched, the electric charge that has been charged in the discharge capacity 29 flows to the optical modulation element 4 and the electrostatic discharge withstand element 5. At this time, the voltage 35 applied to the optical modulation element 4 is determined by the ratio of the combined capacitance of the electrostatic capacitance 33 and the electrostatic capacitance 34 to the discharge capacity 29. As the combined capacitance increases, the voltage applied to the optical modulation element 4 decreases. FIG. 9 shows an example of the time variation of voltage applied to the optical modulation element 4 when a static electricity of 100 V is applied. In FIG. 9, the dotted line shows the case where there is no electrostatic discharge withstand element 5, and the solid line shows the case where the electrostatic discharge withstand element 5 is connected in parallel to the optical modulation element 4. In the case of the HBM, the discharge capacity 29 is 100 pF and the discharge resistance 32 is 1.5 kΩ. For example, in the case of the optical semiconductor device with a modulation speed of 100 Gbps, the electrostatic capacitance 33 of the optical modulation element 4 is extremely small, at about 0.1 pF, thereby in the absence of the electrostatic discharge withstand element 5, the voltage applied to the optical modulation element 4 is 100 V, and if the electrostatic breakdown voltage of the optical modulation element 4 were 80 V, the optical modulation element 4 would be destroyed by static electricity. In contrast, if the electrostatic discharge withstand element 5 with 50 pF is connected in parallel to the optical modulation element 4, the combined capacitance becomes 50.1 pF, and thus the voltage 35 applied to the optical modulation element 4 is reduced to about 67 V. If the electrostatic breakdown voltage of the optical modulation element 4 is 80 V, connecting the electrostatic discharge withstand element 5 in parallel with the optical modulation element 4 prevents the optical modulation element 4 from being destroyed by static electricity.

The optical semiconductor device 1 according to Embodiment 1 is characterized in that it is possible to cut the electrical connection between the electrostatic discharge withstand element 5 and the optical modulation element 4 in order to increase the electrostatic breakdown voltage. Electrostatic discharge withstand elements are effective in preventing semiconductor elements built into optical semiconductor devices from being destroyed by static electricity generated by machines or workers during the mounting of optical semiconductor devices on substrates or the like, or during the inspection of the characteristics of optical semiconductor devices. However, after being mounted in optical transmission devices such as transceivers with built-in electrostatic protection circuits, electrostatic discharge withstand elements are no longer needed. On the contrary, in semiconductor devices that perform high-speed modulation, it is necessary to reduce the electrostatic capacitance of parts related to high-speed operation, such as modulation elements, thus the addition of the capacitance of electrostatic discharge withstand elements to modulation elements is undesirable. That is, when optical semiconductor devices, which require an increase in electrostatic breakdown voltage, are being mounted or inspected, electrostatic discharge withstand elements are required to be electrically connected, and after mounting in optical transmission devices such as transceivers, electrostatic discharge withstand elements are required

To be electrically disconnected. The optical semiconductor device according to Embodiment 1 satisfies such a requirement. FIG. 5 is a top view of the optical semiconductor device in which the electrical connection between the optical modulation element 4 and the electrostatic discharge withstand element 5 is disconnected. FIG. 6 is a cross-sectional schematic view of the optical modulation element 4 and the electrostatic discharge withstand element 5 along the broken line indicated by D-D line in FIG. 5. As shown in FIG. 1, the optical modulation element 4 and the electrostatic discharge withstand element 5 are electrically connected through the temporary electrode 10, thus, to disconnect the electrical connection between both elements, it is only necessary to remove the temporary electrode 10. The optical semiconductor device 1 according to Embodiment 1 is characterized in that the optical modulation element 4 and the electrostatic discharge withstand element 5 are electrically connected through the temporary electrode 10, so that it is easier to disconnect the electrical connection between both elements, compared to, for example, when both elements are formed with a single electrode. For example, the temporary electrode 10 can be cut using a scratch or laser trimming, but this is not the only method, and methods such as dissolving using heat treatment or chemical treatment can also be applied as desired. After mounting on the optical transmission device such as a transceiver, the temporary electrode 10 is cut and thus the structure shown in FIGS. 5 and 6 is formed, so that the influence of the capacitance of the electrostatic discharge withstand element 5 on the optical modulation element 4 disappears, allowing the optical semiconductor device 1 to operate high-speed modulation.

The effects of Embodiment 1 will be explained while comparing with the prior art. In Patent Document 1, the structure is such that the electrical connection between the semiconductor laser and the electrostatic discharge withstand element cannot be disconnected, and when the electrostatic discharge withstand element is similarly provided for the optical modulation element, the electrostatic capacitance of the electrostatic discharge withstand element is added to the optical modulation element. As a result, the high electrostatic capacitance of the optical modulation element prevents high-speed operation, SO that it cannot be used for high-speed modulation applications. On the other hand, the technology disclosed in the present disclosure can be applied to optical semiconductor devices with high-speed modulation because this technology improves the electrostatic breakdown voltage of the optical modulation element without complicating the manufacturing process or requiring additional components, and because the electrical connection between the electrostatic discharge withstand element and the optical modulation element can be disconnected later.

The method for manufacturing the above-mentioned optical semiconductor device 1 will be briefly explained. The n-type guide layer 12 is crystal-grown on the surface of the semiconductor substrate 11 using a metal organic chemical vapor deposition (MOCVD) method. The active layer 13, the light absorption layer 20, the diffraction grating 14, and the p-type guide layer 15 are formed by crystal growth using the MOCVD method and dry etching using a SiO₂ mask in each area of the semiconductor laser 2, the isolation section 3, and the optical modulation element 4, which are on the surface of the guide layer 12. The SiO₂ mask is formed on the surface of the guide layer 15 with the same shape as the surface shape of the mesa stripe 16, and then the mesa stripe 16 is formed by dry etching using the SiO₂ mask. Subsequently, the buried layer 27 is crystal-grown on the exposed portions on both sides of the mesa stripe 16. Then, the SiO₂ mask is removed, and the p-type cladding layer 17, the contact layer 18a, and the contact layer 18b are sequentially crystal-grown on the surfaces of buried layer 27 and the mesa stripe 16. Then, the contact layer 18b on the isolation section 3 is removed by wet etching using a photoresist mask.

The insulating film 21 such as SiN or SiO₂ is formed on the surfaces of the semiconductor laser 2, the isolation section 3, and the optical modulation element 4 using a plasma CVD method or other methods. Opening portions are formed in the insulating film 21 by combining photolithography technology and etching technology using hydrofluoric acid or other chemicals, in the area where the electrode is to be formed. Then, the first electrode layer 22, which consists of Ti/Pt/Au, and the second electrode layer 23, which includes an Au layer, are formed in order from the semiconductor layer side. The anode electrodes 6, 7, and 9, which are composed of the first electrode layer 22 and the second electrode layer 23, are formed in the opening portions of the insulating film 21 by using electron beam deposition, plating, and the like, and then the unnecessary portions are lifted off together with the photoresist film. At this time, the bonding pad electrode 8 connected to the anode electrode 7, and the temporary electrode 10 connected to the anode electrode 7 and the anode electrode 9 are formed at the same time. Subsequently, the back surface of the semiconductor substrate 11 is polished, and then the cathode electrode 26 is formed on the back surface of the semiconductor substrate 11. The cathode electrode 26 is composed of the first electrode layer 24 of the AuGe/Ni/Ti/Pt/Au structure and the second electrode layer 25 including an Au layer. Note that, the electrode structures of the first electrode layer 22, the second electrode layer 23, the first electrode layer 24, and the second electrode layer 25 shown here are just examples, and the electrode structure is not limited, and any electrode structure can be applied within the scope of not deviating from the content of the present disclosure. The above processes enable the manufacturing of the optical semiconductor device 1 according to Embodiment 1.

Note that the material shown in Embodiment 1 is an example, and is not limited thereto. The active layer 13 and the light absorption layer 20 are composed of the MQW structure, but the quantum well layer may be a single layer or these layers may not be composed of the MQW structure. FIG. 2 shows a case where the isolation section 3 and the optical modulation element 4 are formed of the same stacked semiconductor layers, but they may be formed of semiconductors of different compositions. FIG. 2 shows an example where the diffraction grating 14 is formed on the active layer 13, but it may be formed under the active layer 13. The cladding layer 17, the contact layer 18a, and the contact layer 18b are commonly formed in the regions of the semiconductor laser 2, the isolation section 3, and the optical modulation element 4, but these layers may be formed individually in separate steps. FIG. 4 shows an example where the electrostatic discharge withstand element 5 has the same layer structure as the optical modulation element 4, but the electrostatic discharge withstand element 5 may have the same layer structure as the semiconductor laser 2. FIG. 1 shows an example where the mesa stripe 16 of the semiconductor laser 2, the isolation section 3, and the optical modulation element 4 are each the same width, but the width of each part may not be the same. In FIGS. 3 and 4, the semiconductor laser 2 and the optical modulation element 4 are configured as a buried structure, but other structures such as a ridge structure are also applicable. Instead of connecting the anode electrode 7 of the optical modulation element 4 and the anode electrode 9 of the electrostatic discharge withstand element 5 with the temporary electrode 10, the anode electrode 7 and the anode electrode 9 may be connected by wire bonding.

Next, the method for manufacturing the optical transmission device that uses the optical semiconductor device 1 will be explained.

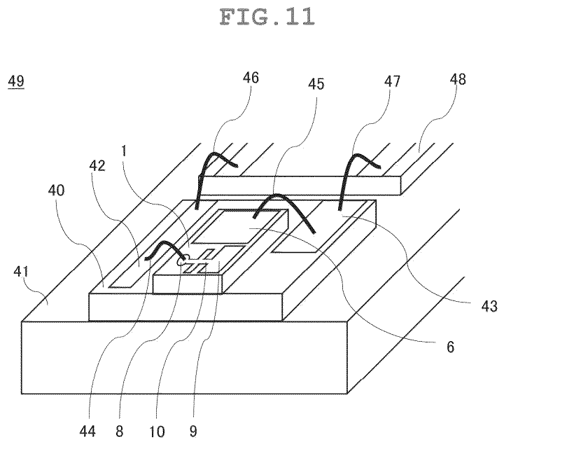

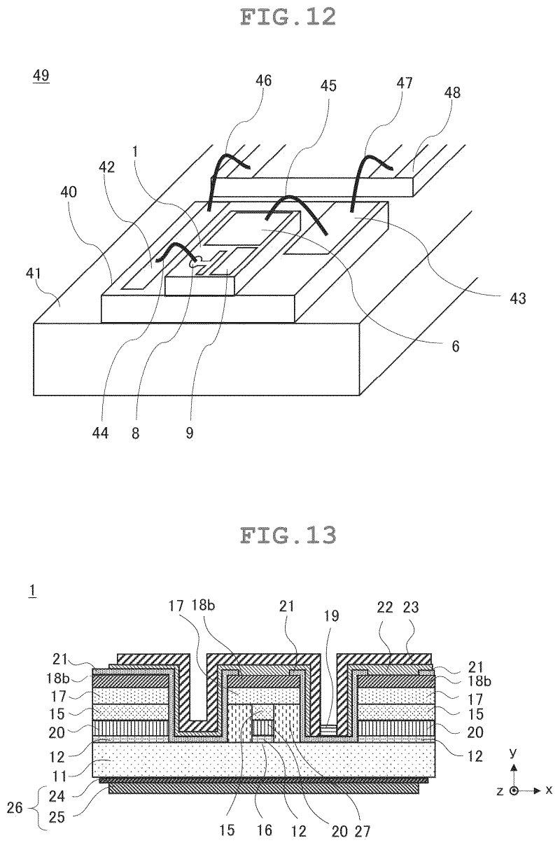

The method for manufacturing the optical transmission device that uses the optical semiconductor device 1 includes: a step of disposing the optical semiconductor device on the sub-mount; a step of electrically connecting the optical semiconductor device and the drive circuit; and a step of electrically cutting the temporary electrode of the optical semiconductor device disposed on the sub-mount. The optical transmission device in each manufacturing process is shown in FIGS. 10, 11, and 12. FIG. 10 is a perspective view of the optical transmission device in the step of disposing the optical semiconductor device on the sub-mount. FIG. 11 is a perspective view of the optical transmission device in the step of electrically connecting the optical semiconductor device and the drive circuit. FIG. 12 is a perspective view of the optical transmission device in the step of electrically cutting the temporary electrode of the optical semiconductor device disposed on the sub-mount.

First, in the step of disposing the optical semiconductor device on the sub-mount, as shown in FIG. 10, the optical semiconductor device 1 is disposed on the sub-mount 40 of the optical transmission device 49. As a method of disposing the optical semiconductor device 1 on the sub-mount 40, for example, die bonding using solder is used. The sub-mount 40 has signal lines 42, 43 for transmitting electrical signals, and is die-bonded to the substrate 41. In general, the substrate 41 functions as a heat sink for dissipating the heat generated by the optical semiconductor device 1 to the outside, or as a thermoelectric controller for adjusting the temperature of the optical semiconductor device 1. The substrate 41 also has a drive circuit 48 that inputs and outputs electrical signals to and from the optical semiconductor device 1. The drive circuit 48 includes not only the circuit for the optical semiconductor device 1, but also an electrical circuit for controlling the thermoelectric controller on the substrate 41, and a circuit for preventing electrostatic discharge (Electro-Static Discharge: ESD) to the optical semiconductor device 1. In addition, a photodiode element that monitors the optical output of the optical semiconductor device 1, and the like are mounted on the sub-mount 40 or the substrate 41, but diagrams and explanations thereof are omitted.

Next, in the step of electrically connecting the optical semiconductor device and the drive circuit, as shown in FIG. 11, wire bonding is performed to input and output electrical signals between the drive circuit 48 and the optical semiconductor device 1. First, wire bonding is performed from the bonding pad electrode 8 connected to the optical modulation element 4 of the optical semiconductor device 1 to the signal line 42 on the sub-mount 40. Then, wire bonding is performed from the anode electrode 6 of the semiconductor laser 2 of the optical semiconductor device 1 to the signal line 43 on the sub-mount 40. Then, wire bonding is performed from the signal lines 42, 43 to the drive circuit 48. For example, an Au wire is used for the wire, but the wire is not limited to the Au wire. In addition, the order of wire bonding is not limited to the order described above.

Secondly, in the step of electrically cutting the temporary electrode of the optical semiconductor device disposed on the sub-mount, as shown in FIG. 12, the temporary electrode 10 is cut to separate the electrical connection between the optical modulation element 4 and the electrostatic discharge withstand element 5. Wiring the wire 44 and the wire 46 connects the optical modulation element 4 to the ESD protection circuit of the drive circuit 48, thereby eliminating the need for the electrostatic discharge withstand element 5. As a method for cutting the temporary electrode 10, for example, the temporary electrode 10 is peeled off by scratching it with a probe needle, and thus the electrical connection between the optical modulation element 4 and the electrostatic discharge withstand element 5 is disconnected. The method of cutting the temporary electrode 10 is not limited to scratching, and a cutting method that is appropriate for the material and form of the temporary electrode 10 can be applied. For example, a method of cutting by laser trimming can also be applied. Cutting the temporary electrode 10 electrically separates the capacitance of the electrostatic discharge withstand element 5 from the optical modulation element 4. As a result, the optical transmission device 49 capable of high-speed modulation is provided.

Applying the method for manufacturing the optical transmission device configured in the manner described above enables the temporary electrode of the optical semiconductor device to be cut after the optical semiconductor device has been mounted on the optical transmission device, thus providing the optical transmission device capable of high-speed modulation while using the optical semiconductor device with a high electrostatic breakdown voltage for the optical modulation element.

As described above, the optical semiconductor device according to Embodiment 1 comprises: the semiconductor laser formed above the semiconductor substrate; the optical modulation element formed above the semiconductor substrate; the electrostatic discharge withstand element formed above the semiconductor substrate; and the temporary electrode electrically connecting the optical modulation element and the electrostatic discharge withstand element in parallel, wherein the electrostatic capacitance of the electrostatic discharge withstand element is separated from the optical modulation element by the temporary electrode being electrically disconnected.

The optical semiconductor device configured in the manner described above can increase the electrostatic breakdown voltage of the optical modulation element. Furthermore, because the temporary electrode can be cut after being mounted in the optical transmission device, the electrostatic capacitance of the electrostatic discharge withstand element can be separated from the electrostatic capacitance of the optical modulation element, and thus the optical semiconductor device and the optical transmission device equipped with the optical semiconductor device can be operated for high-speed modulation applications.

Therefore, applying the optical semiconductor device according to Embodiment 1 provides an optical transmission device capable of high-speed modulation while improving the electrostatic breakdown voltage during mounting, and an optical semiconductor device suitable for the optical transmission device.

### Embodiment 2

An optical semiconductor device of Embodiment 2 differs from that of Embodiment 1 in that the first electrode layer of the temporary electrode 10 does not contain Ti. It is known that, as a technology for electrodes applied to semiconductor devices, the adhesion between the electrode and the object on which the electrode is formed is improved by containing Ti in the lower layer of the electrode. That is, by not containing Ti in the first electrode layer, which is the lower layer of the temporary electrode 10, the adhesion between the temporary electrode 10 and the insulating film 21 is weaker than when the first electrode layer contains Ti, and thus the temporary electrode 10 can be more easily cut.

Applying an optical semiconductor device configured in the manner described above enables the electrostatic breakdown voltage of the optical modulation element 4 to be increased. Furthermore, because the temporary electrode 10 can be more easily cut after being mounted on the optical transmission device, the electrostatic capacitance of the electrostatic discharge withstand element 5 can be separated from the electrostatic capacitance of the optical modulation element 4, enabling an optical transmission device to be used for high-speed modulation applications.

Therefore, applying the optical semiconductor device according to Embodiment 2 enables the electrostatic breakdown voltage during mounting to be improved, and the electrostatic capacitance of the electrostatic discharge withstand element to be more easily separated from the electrostatic capacitance of the optical modulation element, thus providing an optical transmission device capable of high-speed modulation and an optical semiconductor device suitable for the optical transmission device.

### Embodiment 3

The optical semiconductor device of Embodiment 3 differs from that of Embodiment 1 in that the first electrode layer of the anode electrode 9 of the electrostatic discharge withstand element 5 does not contain Ti. By not containing Ti in the first electrode layer, which is the lower layer of the anode electrode 9, the adhesion between the anode electrode 9 and the contact layer 18b is weaker than when the first electrode layer contains Ti, and thus the anode electrode 9 can be peeled off more easily. For example, the anode electrode 9 of the electrostatic discharge withstand element 5 can be torn off by picking up the end of the anode electrode 9 with tweezers and lifting it off the semiconductor surface. In particular, since the anode electrode 9 of the electrostatic discharge withstand element 5 is assumed to be formed over as large an area as possible, workability is improved compared to directly cutting the temporary electrode 10 as in Embodiment 1. In addition, since removing the anode electrode 9 is effectively equivalent to cutting the temporary electrode 10, the same effect can be obtained as when the temporary electrode 10 is directly cut.

In addition to the first electrode layer of the temporary electrode 10 that does not contain Ti, as in Embodiment 2, the first electrode layer of the anode electrode 9 that does not contain Ti allows the anode electrode 9 to be peeled off together with the temporary electrode 10, thereby achieving the effect of more easily and workably separating the electrostatic capacitance of the electrostatic discharge withstand element 5 from the electrostatic capacitance of the optical modulation element 4.

Applying an optical semiconductor device configured in the manner described above enables the electrostatic breakdown voltage of the optical modulation element 4 to be increased. Furthermore, because the temporary electrode 10 can be cut more easily and with better workability after being mounted on the optical transmission device, the electrostatic capacitance of the electrostatic discharge withstand element 5 can be separated from the electrostatic capacitance of the optical modulation element 4, enabling an optical transmission device to be used for high-speed modulation applications.

Therefore, applying the optical semiconductor device according to Embodiment 3 enables the electrostatic breakdown voltage during mounting to be improved, and the electrostatic capacitance of the electrostatic discharge withstand element to be more easily and with better workability separated from the electrostatic capacitance of the optical modulation element, thus providing an optical transmission device capable of high-speed modulation and an optical semiconductor device suitable for the optical transmission device.

### Embodiment 4

FIG. 13 is a cross-sectional schematic view of an optical semiconductor device according to Embodiment 4. The optical semiconductor device of Embodiment 4 differs from that of Embodiment 1 in that the temporary electrode 10 is composed of a metal film 19 with a melting point lower than that of a metal film that constitutes the anode electrode 7 of the optical modulation element 4. The other basic effects are the same as in Embodiment 1, but compared to Embodiment 1, the electrical connection between the optical modulation element 4 and the electrostatic discharge withstand element 5 can be more easily cut. Specifically, the electrical connection between the optical modulation element 4 and the electrostatic discharge withstand element 5 can be cut by flowing a current from the bonding pad electrode 8 of the optical modulation element 4 to the anode electrode 9 of the electrostatic discharge withstand element 5, or in the opposite direction, and thus melting the temporary electrode 10, which has a lower melting point, using the Joule heat generated. The metal film 19 that constitutes the temporary electrode 10 can be selected freely from AuSn solder, Sn—Ag solder, Sn—Cu solder or the like, based on the relative relationship with the melting points or the like of other electrodes. In addition, the current value at which the temporary electrode 10 melts can be adjusted by adjusting not only the material of the metal film 19, but also the cross-sectional area and the length of the temporary electrode 10.

Applying an optical semiconductor device configured in the manner described above enables the electrostatic breakdown voltage of the optical modulation element 4 to be increased. Furthermore, after being mounted on the optical transmission device, the temporary electrode 10 can be easily cut by heat, SO that the electrostatic capacitance of the electrostatic discharge withstand element 5 can be separated from the electrostatic capacitance of the optical modulation element 4, thus providing an optical transmission device capable of high-speed modulation application applications.

Therefore, applying the optical semiconductor device according to Embodiment 4 enables the electrostatic breakdown voltage during mounting to be improved, and the electrostatic capacitance of the electrostatic discharge withstand element to be more easily separated from the electrostatic capacitance of the optical modulation element by heat, thus providing an optical transmission device capable of high-speed modulation and an optical semiconductor device suitable for the optical transmission device.

### Embodiment 5

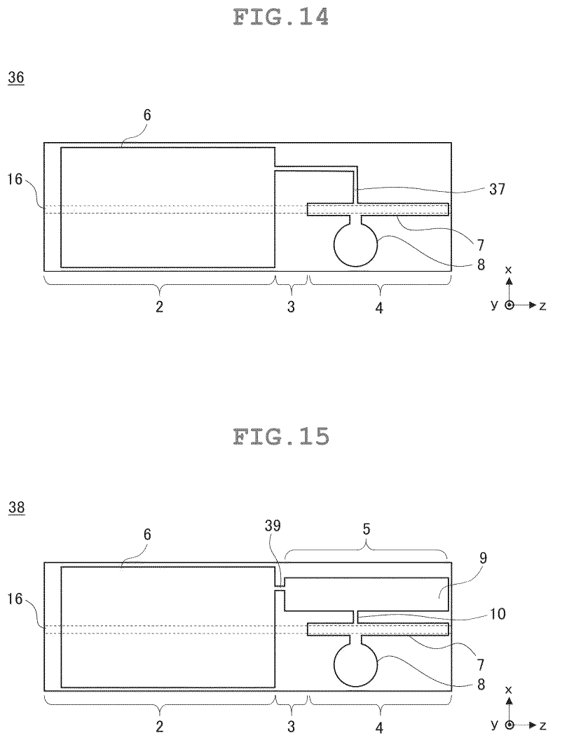

FIG. 14 is a top view of an optical semiconductor device according to Embodiment 5.

The optical semiconductor device 36 of Embodiment 5 differs from that of Embodiment 1 in that a temporary electrode 37 connects the anode electrode 7 of the optical modulation element 4 and the anode electrode 6 of the semiconductor laser 2. Connecting the anode electrode 7 of the optical modulation element 4 to the anode electrode 6 of the semiconductor laser 2 allows the semiconductor laser 2 to function as an electrostatic discharge withstand element in the optical semiconductor device 36, without the need to form an electrostatic discharge withstand element individually. The optical semiconductor device 36 is particularly effective when the characteristics of the optical semiconductor device are not tested before being mounted on an optical transmission device such as a transceiver, and compared to Embodiments 1, 2, 3, and 4, the anode electrode of the electrostatic discharge withstand element does not need to be formed, thus reducing the cost of the electrode material.

Applying an optical semiconductor device configured in the manner described above enables the electrostatic breakdown voltage of the optical modulation element 4 to be increased without forming individual electrostatic discharge withstand elements. Furthermore, because the temporary electrode 37 can be cut after being mounted on the optical transmission device, the electrostatic capacitance of the semiconductor laser 2 can be separated from the electrostatic capacitance of the optical modulation element 4, enabling the optical transmission device to be used for high-speed modulation applications.

Therefore, applying the optical semiconductor device according to Embodiment 5 enables the electrostatic breakdown voltage during mounting to be improved without forming individual electrostatic discharge withstand elements, thus providing an optical transmission device capable of high-speed modulation and an optical semiconductor device suitable for the optical transmission device.

### Embodiment 6

FIG. 15 is a top view of an optical semiconductor device according to Embodiment 6.

The optical semiconductor device 38 of Embodiment 6 differs from that of Embodiment 1 in that the anode electrode 9 of the electrostatic discharge withstand element 5 and the anode electrode 6 of the semiconductor laser 2 are connected by a temporary electrode 39. Connecting the anode electrode 9 of the electrostatic discharge withstand element 5 to the anode electrode 6 of the semiconductor laser 2 with the temporary electrode 39 means that both the semiconductor laser 2 and the electrostatic discharge withstand element 5, which is separate from the semiconductor laser 2, function as electrostatic discharge withstand elements. That is, by connecting the anode electrode 9 of the electrostatic discharge withstand element 5 and the anode electrode 6 of the semiconductor laser 2 with the temporary electrode 39, the electrostatic capacitance of the electrostatic discharge withstand element 5 and the electrostatic capacitance of the semiconductor laser 2 are connected to the optical modulation element 4, thus improving the electrostatic breakdown voltage compared to when either one of the elements is connected.

Applying an optical semiconductor device configured in the manner described above enables the electrostatic breakdown voltage of the optical modulation element 4 to be increased compared to the Embodiment 1. Furthermore, because the temporary electrode 10 can be cut after being mounted on the optical transmission device, the electrostatic capacitance of the electrostatic discharge withstand element 5 and the electrostatic capacitance of the semiconductor laser 2 can be separated from the electrostatic capacitance of the optical modulation element 4, enabling the optical transmission device to be used for high-speed modulation applications.

Therefore, applying the optical semiconductor device according to Embodiment 6 enables the electrostatic breakdown voltage during mounting to be further improved, thus providing an optical transmission device capable of high-speed modulation and an optical semiconductor device suitable for the optical transmission device.

### Modification 1 of Embodiment 6

In Embodiment 6, an example is given in which the temporary electrode 39 connects the anode electrode 9 of the electrostatic discharge withstand element 5 to the anode electrode 6 of the semiconductor laser 2. As a modification of Embodiment 6, the temporary electrode 39 may be connected to the anode electrode 6 of the semiconductor laser 2 and the anode electrode 7 of the optical modulation element 4 or the bonding pad electrode 8. That is, the temporary electrode 39 may connect the anode electrode 7 of the optical modulation element 4 or the bonding pad electrode 8 to the anode electrode 6 of the semiconductor laser 2 without the anode electrode 9 of the electrostatic discharge withstand element 5. In this case, as in Embodiment 6, both the semiconductor laser 2 and the electrostatic discharge withstand element 5, which is separate from the semiconductor laser 2, function as electrostatic discharge withstand elements, and even if either the electrostatic discharge withstand element 5 or the semiconductor laser 2 does not function as an electrostatic discharge withstand element, one of them can function as an electrostatic discharge withstand element, thus the manufacturing yield can be improved.

Applying an optical semiconductor device configured in the manner described above enables the electrostatic breakdown voltage of the optical modulation element 4 to be increased while improving the yield rate. Furthermore, because the temporary electrode 10 and the temporary electrode 39 can be cut after being mounted on the optical transmission device, the electrostatic capacitance of the electrostatic discharge withstand element 5 and the electrostatic capacitance of the semiconductor laser 2 can be separated from the electrostatic capacitance of the optical modulation element 4, enabling the optical semiconductor device to be used for high-speed modulation applications.

Therefore, applying the optical semiconductor device according to Modification 1 of Embodiment 6 enables the electrostatic breakdown voltage during mounting to be improved while improving the yield rate, thus providing an optical transmission device capable of high-speed modulation and an optical semiconductor device suitable for the optical transmission device.

Note that, within the scope of not being contradictory, it is possible to freely combine each embodiment or to transform or omit each embodiment as appropriate.

### DESCRIPTION OF THE REFERENCE CHARACTERS

1 optical semiconductor device
2 semiconductor laser
3 isolation section
4 optical modulation element
5 electrostatic discharge withstand element
6 anode electrode
7 anode electrode
8 bonding pad electrode
9 anode electrode
10 temporary electrode
11 semiconductor substrate
12 guide layer
13 active layer
14 diffraction grating
15 guide layer
16 mesa stripe
17 cladding layer
18a contact layer
18b contact layer
19 metal film
20 light absorption layer
21 insulating film
22 first electrode layer
23 second electrode layer
24 first electrode layer
25 second electrode layer
26 cathode electrode
27 buried layer
28 voltage source
29 discharge capacity
30 protective resistance
31 switch
32 discharge resistance
33 electrostatic capacitance
34 electrostatic capacitance
35 voltage
36 optical semiconductor device
37 temporary electrode
38 optical semiconductor device
39 temporary electrode
40 sub-mount
41 substrate
42 signal line
43 signal line
44 wire
45 wire
46 wire
47 wire
48 drive circuit
49 optical transmission device

1. A method for manufacturing an optical transmission device comprising the steps of:
disposing an optical semiconductor device on a sub-mount, the optical semiconductor device including a semiconductor laser formed above a semiconductor substrate, an optical modulation element formed above the semiconductor substrate, an electrostatic discharge withstand element formed above the semiconductor substrate, and a temporary electrode electrically connecting the optical modulation element and the electrostatic discharge withstand element in parallel;
connecting electrically the optical semiconductor device and a drive circuit; and
cutting electrically the temporary electrode of the optical semiconductor device disposed on the sub-mount.

2. An optical semiconductor device comprising:
a semiconductor laser formed above a semiconductor substrate;
an optical modulation element formed above the semiconductor substrate;
an electrostatic discharge withstand element formed above the semiconductor substrate; and
a temporary electrode electrically connecting the optical modulation element and the electrostatic discharge withstand element in parallel, wherein
the electrostatic capacitance of the electrostatic discharge withstand element is separated from the optical modulation element by the temporary electrode being electrically disconnected.

3. The optical semiconductor device according to claim 2, wherein
a first electrode layer of the temporary electrode is made of a metal that does not contain Ti.

4. The optical semiconductor device according to claim 2, wherein
a first electrode layer of an anode electrode of the electrostatic discharge withstand element is made of a metal that does not contain Ti.

5. The optical semiconductor device according to claim 2, wherein
the temporary electrode is made of a metal having a melting point lower than that of the metal that constitutes the anode electrode of the optical modulation element.

6. The optical semiconductor device according to claim 2, wherein
the electrostatic discharge withstand element is the semiconductor laser.

7. The optical semiconductor device according to claim 2, wherein
the electrostatic discharge withstand element includes the semiconductor laser and the electrostatic discharge withstand element other than the semiconductor laser.

8. The optical semiconductor device according to claim 7, wherein
the anode electrode of the semiconductor laser is connected to the anode electrode of the optical modulation element through the anode electrode of the electrostatic discharge withstand element other than the semiconductor laser.

9. The optical semiconductor device according to claim 7, wherein
the anode electrode of the semiconductor laser is connected to the anode electrode of the optical modulation element without being connected to the anode electrode of the electrostatic discharge withstand element other than the semiconductor laser.

10. An optical transmission device comprising:
the optical semiconductor device according to claim 2; and
a drive circuit electrically connected to the optical semiconductor device.
